(19) United States
(12) Patent Application Publication
(10) Pub. No.: US 2015/0056795 A1
(43) Pub. Date: Feb. 26, 2015

(54) METHOD OF MANUFACTURING SEMICONDUCTOR DEVICE

(71) Applicant: SAMSUNG ELECTRONICS CO., LTD, Gyeonggi-do (KR)

(72) Inventors: Bo-kyeong Kang, Seoul (KR); Bo-un Yoon, Seoul (KR); Il-young Yoon, Gyeonggi-do (KR); Jae-kwang Choi, Gyeonggi-do (KR); Ho-young Kim, Gyeonggi-do (KR); Se-jung Park, Gyeonggi-do (KR); Jae-seok Kim, Seoul (KR)

(21) Appl. No.: 14/445,284

(22) Filed: Jul. 29, 2014

(30) Foreign Application Priority Data
Aug. 21, 2013 (KR) 10-2013-0099233

(51) Int. Cl. H01L 29/66; H01L 21/321; H01L 21/3213; H01L 21/28

(52) U.S. Cl. CPC H01L 29/66795; H01L 21/28008; H01L 21/3212; H01L 21/32135
USPC 438/585

(57) ABSTRACT

A method of manufacturing a semiconductor devices includes providing a semiconductor substrate that includes a channel region. The method includes forming a gate electrode material film including a stepped portion on the channel region. A sacrificial material film that has an etch selectivity that is the same as an etch selectivity of the gate electrode material film is formed. The sacrificial material film is planarized until a top surface of the gate electrode material film is exposed. The stepped portion is reduced by removing an exposed portion of the gate electrode material film.

### CROSS-REFERENCE TO RELATED APPLICATION

This application claims priority under 35 U.S.C. §119 to Korean Patent Application No. 10-2013-0099233, filed on Aug. 21, 2013, in the Korean Intellectual Property Office, the disclosure of which is incorporated by reference herein in its entirety.

### TECHNICAL FIELD

Exemplary embodiments of the present inventive concept relate to a semiconductor device, and more particularly, to a method of manufacturing a semiconductor device.

### DISCUSSION OF RELATED ART

As a storage capacity of a semiconductor device increases, a density of the semiconductor device and the degree of integration of the semiconductor device per unit area may increase. The density of the semiconductor device may be increased by reducing a size of each semiconductor device and reducing an interval between semiconductor devices, When a size of a horizontal channel semiconductor device is reduced, a length of a channel may be reduced and a short-channel effect, by which the semiconductor device behaves abnormally, may occur. A semiconductor device which has sufficient effective channel length and increases a value of operating current may have a fin on a gate such as a fin field-effect transistor (FinFET). Chemical mechanical polishing may be used to planarize stepped portion of a gate poly film that is formed due to a height of the fin in the FinFET.

### SUMMARY

Exemplary embodiments of the present inventive concept provide a method of planarizing a semiconductor device by chemical mechanical polishing. Exemplary embodiments of the inventive concept may include an end point detector (EPD) method using a selectivity difference between films, which may minimize a variation which may occur by dry etching and wet etching. A stepped portion of a gate electrode material film that is formed according to a height of a fin may be removed.

According to an exemplary embodiment of the present inventive concept, a method of manufacturing a semiconductor device includes providing a semiconductor substrate that includes a channel region. A gate electrode material film that has a stepped portion is formed on the channel region. A sacrificial material film that has an etch selectivity that is the same as an etch selectivity of the gate electrode material film may be formed on the gate electrode material film The sacrificial material film may be planarized until a top surface of the gate electrode material film is exposed. The stepped portion of the gate electrode material film may he reduced by removing an exposed portion of the gate electrode material film.

The reducing of the stepped portion of the gate electrode material film may include removing the exposed portion of the gate electrode material film by using the sacrificial material film as an etching mask.

The sacrificial material film may be removed after using the sacrificial material film as an etching mask.

The stepped portion may be removed by etching the gate electrode material film by chemical mechanical polishing after the removing of the sacrificial material film.

The removing of the stepped portion may be performed for a predetermined polishing time.

The planarizing of the sacrificial material film may include chemical mechanical polishing.

The planarizing, the sacrificial material film may include etching the sacrificial material film by an end point detector (EPD) process using a selectivity difference between the gate electrode material film and the sacrificial material film.

The planarizing of the sacrificial material film may further include over-etching the sacrificial material film so that a top surface of the sacrificial material film is lower than the top surface of the gate electrode material film.

The gate electrode material film may be etched by dry etching.

The reducing of the stepped portion of the gate electrode material film may include reducing the stepped portion by etching the gate electrode material film and the sacrificial material film. The gate electrode material film and the sacrificial material film may he removed at substantially the same etch rate.

According to an exemplary embodiment of the present inventive concept, a method of manufacturing a semiconductor device includes providing a semiconductor substrate that includes a channel region. A gate electrode material film including a stepped portion is formed on the channel region. A sacrificial material film that has an each selectivity that is the same as an etch selectivity of the gate electrode material film is formed. The sacrificial material film is etched until a top surface of the gate electrode material film is exposed. The stepped portion is planarized by etching the gate electrode material film and the sacrificial material film to a predetermined depth without a selectivity.

The etching of the sacrificial material film may include chemical mechanical polishing.

The etching of the gate electrode material film and the sacrificial material film may include etching the gate electrode material film and the sacrificial material film at substantially the same etch speed.

The etching of the gate electrode material film and the sacrificial material film may include a gas cluster ion beam (GCIB) process.

An oxide film that is formed when the GCIB process is used may he removed.

### BRIEF DESCRIPTION OF THE DRAWINGS

The above and other features of the inventive concept will become more apparent by describing in detail exemplary embodiments thereof, with reference to the accompanying drawings in which:

FIG. 1A is a perspective view illustrating a fin field-effect transistor (FinFET) semiconductor device, according to an exemplary embodiment of the present inventive concept;

FIG. 1B is a cross-sectional view taken along line A-A′ of FIG. 1A;

FIGS. 2A through 2F are cross-sectional views showing a method of planarizing a semiconductor device by removing a stepped portion of a gate electrode material film, according to an exemplary embodiment of the present inventive concept;

FIGS. 3A through 3B are cross-sectional views showing a method of planarizing the gate electrode material film when a sacrificial film is over-etched to be lower than the stepped portion that is formed due to a height of a gate according to an exemplary embodiment of the present inventive concept;

FIGS. 4A and 4B are cross-sectional views showing a process of removing the stepped portion of the gate electrode material film by uniformly etching the gate electrode material film and the sacrificial material film without a selectivity in the operation of FIG. 2C according to an exemplary embodiment of the present inventive concept;

FIG. 4C is a cross-sectional view illustrating an oxide film that is formed during etching using a gas cluster ion beam (GCIB) process in the operation of FIG. 4A;

FIG. 5 is a plan view illustrating a memory module including a semiconductor device, according to an exemplary embodiment of the present inventive concept;

FIG. 6 is a block diagram illustrating a memory card including a semiconductor device, according to an exemplary embodiment of the present inventive concept;

FIG. 7 is a block diagram illustrating a memory device including a semiconductor device that is formed by a method of forming an oxide layer, according to an exemplary embodiment of the present inventive concept; and

FIG. 8 is a block diagram illustrating an electronic system including a semiconductor device that is formed by a method of forming an oxide layer, according to an exemplary embodiment of the present inventive concept.

### DETAILED DESCRIPTION OF THE EMBODIMENTS

As used herein, the term “and/or” includes any and all combinations of one or more of the associated listed items. Expressions such as “at least one of,” when preceding a list of elements, modify the entire list of elements and do not modify the individual elements of the list.

Exemplary embodiments of the present inventive concept will now be described more nifty with reference to the accompanying drawings, in which exemplary embodiments of the present inventive concept are shown.

Exemplary embodiments of the present inventive concept may, however, be embodied in many different forms and should not be construed as limited to the exemplary embodiments set forth herein.

Meanwhile, the terminology used herein is for the purpose of describing exemplary embodiments of the present inventive concept, and is not intended to be limiting,

It will be understood that, although the terms first, second, etc. may be used herein to describe various elements, these elements should not be limited by these terms. These terms are only used to distinguish one element from another. For example, a first element could he termed a second element, and, similarly, a second element could be termed a first element, without departing from the scope of exemplary embodiments.

In the drawings, structures or sizes of elements are exaggerated for convenience of explanation and clarity, and parts in the drawings unrelated to the detailed description are omitted to ensure clarity of the inventive concept. In the drawings, the same reference numerals may denote the same elements. In the drawings, dashed lines or dotted lines indicate that layers are formed as different film layers and might not specify physical properties or outer appearances of films. Also, the terms used in the specification have been used to explain the inventive concept and should not be construed as limiting the scope of the inventive concept defined by the claims.

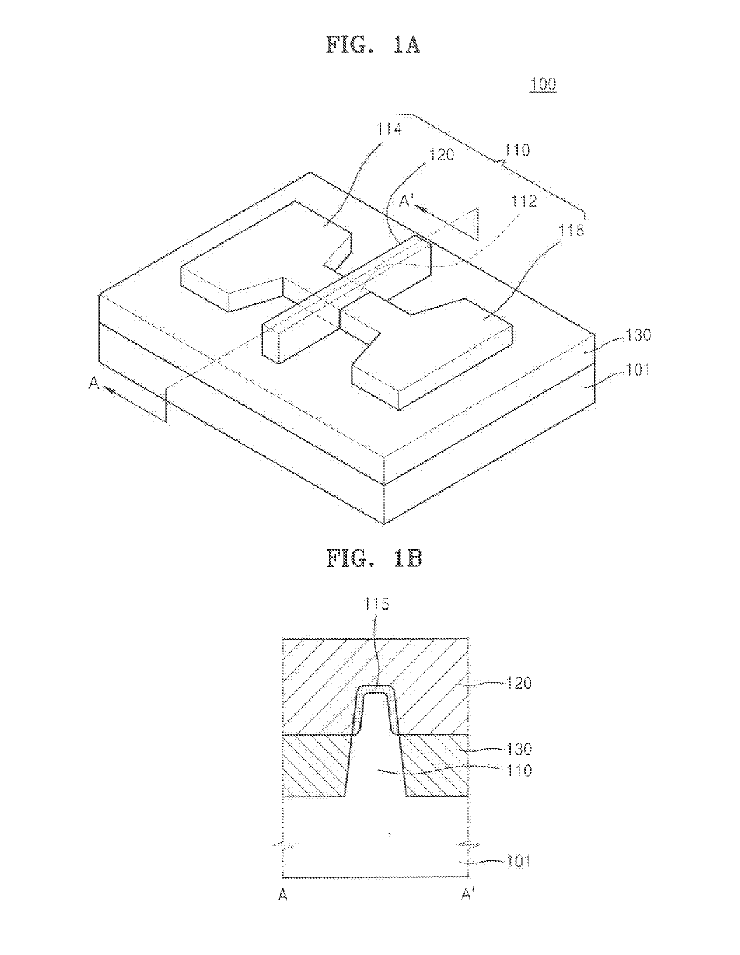

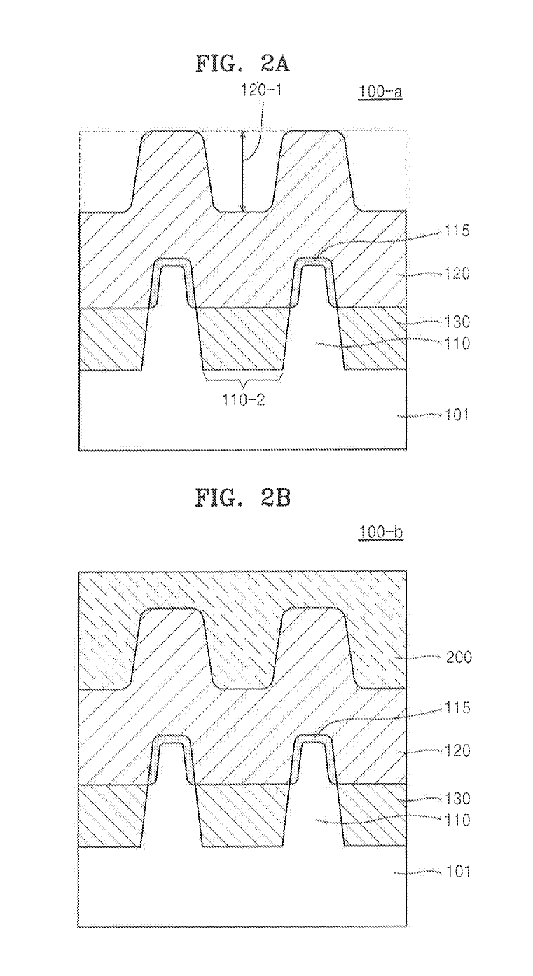

FIG. 1A is a perspective view illustrating a fin field-effect transistor (FinFET) semiconductor device, according to an exemplary embodiment of the present inventive concept.

Referring to FIG. 1A, the semiconductor device 100 may be formed on a semiconductor substrate including a semiconductor, for example, a group IV semiconductor or a group II-VI oxide semiconductor. The semiconductor device 100 may be formed on a bulk substrate 101. Although the semiconductor device 100 may be formed on the bulk substrate 101 in FIG. 1A, it will be understood by one of ordinary skill in the art that the semiconductor device 100 may be formed on another type of substrate. For example, the semiconductor device 100 may be formed on a silicon-on-insulator (SOI) substrate.

The semiconductor device 100 may be formed on the bulk substrate 101, and may be formed on an active region 110 on a device isolation film 130. The active region 110 may include, for example, silicon (Si), and the device isolation film 130 may include silicon oxide.

The active region 110 may include a source region 114, a drain region 116, and a channel region 112 that may be disposed between the source region 114 and the drain region 116.

The channel region 112 may protrude upward as shown in FIG. 1A, for example. When a size of a metal-oxide-semiconductor field-effect transistor (MOSFET) that is a unit semiconductor device of a highly-integrated circuit is reduced, performance and the degree of integration may be increased. A distance between a source and a drain may be reduced, and may lead to a short-channel effect. The channel control ability of a gate may be reduced, and drain-induced barrier lowering (DIBL) may occur. Various 3D gate transistors may be used, For example, a fin field-effect transistor (FinFET) may be used. A semiconductor device of a FinFET may include a gate having a protruding channel region, a channel may be controlled on a plurality of surfaces, and the channel control ability of the gate may be increased.

A gate electrode material film 120 may be formed by being stacked on the channel region 112. The gate electrode material film 120 may be formed by, for example, chemical vapor deposition (CVD) or physical vapor deposition (PVD). The gate electrode material film 120 may include polysilicon (p-Si) or amorphous silicon (a-Si).

FIG. 1B is a cross-sectional view taken along line A-A′ of FIG. 1A.

Referring to FIG. 1B, a semiconductor device 100 that is a FinFET semiconductor device may include the bulk substrate 101, the active region 110, a gate insulating film 115, a gate electrode material film 120, and the device isolation film 130. The bulk substrate 101 may include silicon (Si). The active region 110 may form a stepped portion with a fin shape and a predetermined height. The height of the fin shape may be on the order of hundreds of Å. For example, a stepped portion of a silicon layer due to the fin shape may be 400 Å. The gate insulating film 115 may be formed on a top surface and a side surface of the fin shape of the active region 110. The gate insulating film 115 may separate a gate from the gate electrode material film 120 and may form a channel. The gate insulating film 115 may include a material that is different from that of the active region 110. For example, the gate insulating film 115 may include silicon oxide.

The gate electrode material film 120 may be formed to cover top surfaces of the active region 110, the gate insulating film 115, and the device isolation film 130. The gate electrode material film 120 may be formed by CVD, PVD, or silicon epitaxy.

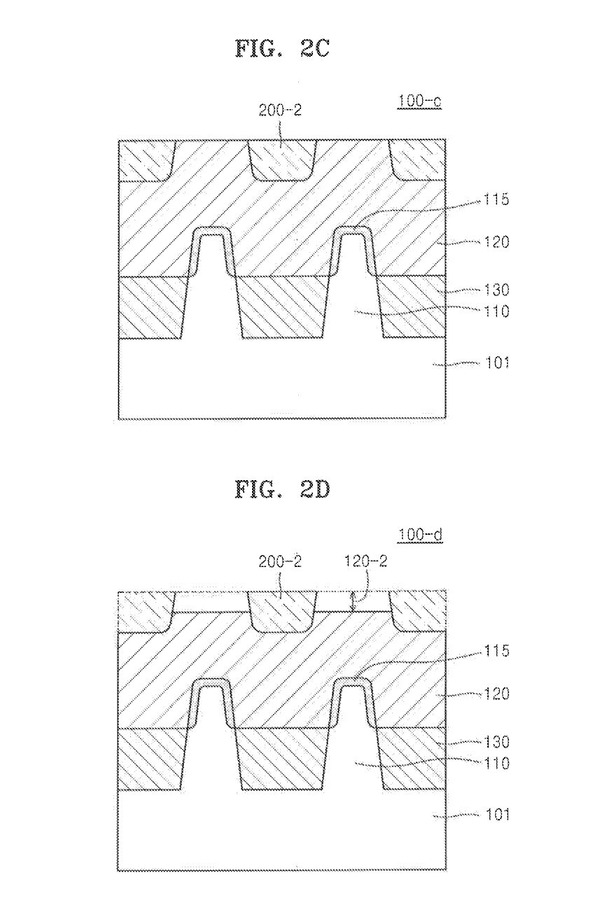

The device isolation film 130 may be formed at sides of the fin shape of the active region 110. The device isolation film 130 may include silicon oxide. As described in FIG. 2, the device isolation film 130 may define an active region 110 and a device isolation region.

In a method of manufacturing a conventional FinFET semiconductor device, a relatively large stepped portion may be formed including a fin having a size of hundreds of A in a device isolation region. Chemical mechanical polishing may be performed to remove the large stepped portion. When the chemical mechanical polishing is performed by calculating a polishing time, a height of a gate need not be obtained.

FIGS. 2A through 2F are cross-sectional views showing a method of manufacturing, the semiconductor device 100 of FIGS. 1A and 1B, according to an exemplary embodiment of the present inventive concept. Although two active regions 110 are shown in FIGS. 2A through 2F, the number of silicon layers each having a fin shape is not limited to

FIG. 2A is a cross-sectional view illustrating a semiconductor device 100-a including at least one fin, and a gate electrode material film 120 that may be formed on the at least one fin and has a stepped portion. Referring to FIG. 2A, the semiconductor device 100-a may include the bulk substrate 101, two active regions 110, the gate insulating film 115, the gate electrode material film 120, and the device isolation film 130. Referring to FIG. 2A, elements may be differently numbered in order to be distinguished from one another.

A first stepped portion 120-1 of the gate electrode material film 120 may be formed according to a height of the at least one fin of the active region 110.

The device isolation film 130 may define the bulk substrate 101 by separating the active region 110 and a device isolation region 110-2. The channel region 112 may be formed in the active region 110 under the gate electrode material film 120.

FIG. 2B is a cross-sectional view showing a process of forming a sacrificial material film 200 on the semiconductor device of FIG. 2A.

Referring to FIG. 2B, the sacrificial material film 200 may be formed on the gate electrode material film 120 of a semiconductor device 100-b having a stepped portion due to a height of a fin. The sacrificial material film 200 may be formed by deposition. The deposition may involve CVD or PVD. The sacrificial material film 200 may include silicon oxide, a carbon-based material, or silicon nitride. The sacrificial material film 200 may include tetra ethoxy silane (TEOS). TEOS may be used as a material for depositing an oxide film. TEOS may be liquid at a room temperature, may have a low temperature at which oxide is formed, and may be used for chemical mechanical polishing using a selectivity difference between the sacrificial material film 200 and the gate electrode material film 120. Examples of a material of the sacrificial material film 200 is not limited to those listed above, and may include any material as long as the material has a selectivity difference from the gate electrode material film 120.

FIG. 2C is a cross-sectional view showing a process of etching the sacrificial material film 200 of FIG. 2B to a predetermined depth.

Referring to FIG. 2C, the sacrificial material film 200 may be partially etched and removed from a semiconductor device 100-c. The sacrificial material film 200 may be removed by etching using a selectivity difference. For example, the sacrificial material film 200, may be etched by an end point detector (EPD) method, until the gate electrode material film 120 is exposed.

The sacrificial material film 200 may be removed by chemical mechanical polishing. The phrase “chemical mechanical polishing” used herein may refer to a process of selectively performing etching by a selectivity difference as described above.

In the chemical mechanical polishing, greater selectivity may increase etching specificity. A ratio of the gate electrode material film 120 to the sacrificial material film 200 may be 1:10 or more. The gate electrode material film 120 may be etched at a rate of 1 whereas the sacrificial material film 200 may be etched at a rate of 10 or more.

When etching is performed by chemical mechanical polishing, the sacrificial material film 200 may be selectively removed. The etching may be stopped when a film different from a film that is being etched is exposed. When a stepped portion of the gate electrode material film 120 is formed according to the active region 110 having a fin shape, a remaining portion 200-2 of the sacrificial material film 200 may remain at a portion corresponding to the stepped portion. For example, when a TEOS film is etched by chemical mechanical polishing, when the gate electrode material film 120 is exposed, the etching may be stepped. However, a part of the TEOS film need not be etched and may remain due to a stepped portion of the gate electrode material film 120. The remaining portion 200-2 of the sacrificial material film 200 may be used as an etching mask.

FIG. 2D is a cross-sectional view showing a process of selectively etching only the gate electrode material film 120 in the semiconductor device of FIG. 2C to a predetermined depth.

Referring to FIG. 2D, in a semiconductor device 100-d, the remaining portion 200-2 of the sacrificial material film 200 may be maintained in substantially the same state as that in FIG. 2C whereas the gate electrode material film 120 may be etched by a second stepped portion 120-2. The sacrificial material film 200 need not be etched and only the gate electrode material film 120 might be etched. Etching may be performed with a high selectivity. A dry recess may be formed by dry etching.

When the sacrificial material film 200 is selected to have a high etch selectivity with respect to the gate electrode material film 120 as described above, the remaining portion 200-2 of the sacrificial material film 200 may act as an etching mask and might not be etched. When the remaining portion 200-2 of the sacrificial material film is a film different from the gate electrode material film 120, the remaining portion 200-2 may include silicon oxide, a carbon-based material, silicon nitride, or TEOS.

FIG. 2E is a cross-sectional view showing a process of removing the sacrificial material film 200 remaining on the semiconductor device of FIG. 2D.

Referring to FIG. 2E, in a semiconductor device 100-e, the remaining portion 200-2 of the sacrificial material film 200 that remains in FIG. 2D may be removed. When the remaining portion 200-2 of the sacrificial material film 200 includes silicon oxide, for example, TEOS, the remaining portion 200-2 may be removed by a method that may remove only TEOS. The remaining portion 200-2 may be removed by wet etching. The wet etching may selectively etch the silicon oxide such as TEOS and may leave other films unetched.

The remaining portion 200-2 of the sacrificial material film 200 may be removed when the sacrificial material film 200 is used as an etching mask and the gate electrode material film 120 is selectively removed by chemical mechanical polishing having a selectivity as shown in FIG. 2D. A third stepped portion 120-3 may remain in the gate electrode material film 120, after the remaining portion 200-2 is removed, according to a height of the remaining portion 200-2 of the sacrificial material film 200. The third stepped portion 120-3 may be smaller than the first stepped portion 120-1.

FIG. 2F is a cross-sectional view showing a semiconductor device 100-f in which the gate electrode material film 120 is uniformly planarized by the series of processes of FIGS. 2A through 2E.

Referring to FIG. 2F, the gate electrode material film 120 of the active region 110 of the FinFET semiconductor device 100-f may have no stepped portion and may be planarized. Referring to FIG. 2F, the third stepped portion 120-3 may exist on the gate electrode material film 120. The third stepped portion 120-3 may be removed by etching. The etching may be chemical mechanical polishing. The chemical mechanical polishing may be performed by calculating a polishing time. The polishing time may be calculated by summing a time taken to remove the third stepped portion 120-3 and a time to remove a predetermined stepped portion. The polishing time may be calculated by adding a time taken to etch a fourth stepped portion 120-4 in FIG. 2F.

Chemical mechanical polishing using a polishing time may have a variable removal rate that is changed as a life time of a consumable member of a device elapses and planarization to a uniform height might not be achieved. When the third stepped portion 120-3 having a relatively small height is etched, the etching may be performed for a relatively short time.

The stepped portion may be removed by chemical mechanical polishing, dry etching, or wet etching through the series of processes of FIGS. 2A through 2F, and the gate electrode material film 120 may be planarized as shown in FIG. 2F. Heights of the first to fourth stepped portions 120-1 to 120-4 are shown in FIG. 2F, and the relative amount of etching performed may be seen. The first stepped portion 120-1 may be generated when the gate electrode material film 120 is first formed. The second stepped portion 120-2 may be generated when the gate electrode material film 120 is etched by using the sacrificial material film 200 as an etching mask. The third stepped portion 120-3 may be formed according to a height of the etching mask that is removed. The fourth stepped portion 120-4 may be generated when the stepped portion 3 120-3 is removed and predetermined etching is additionally performed to achieve planarization.

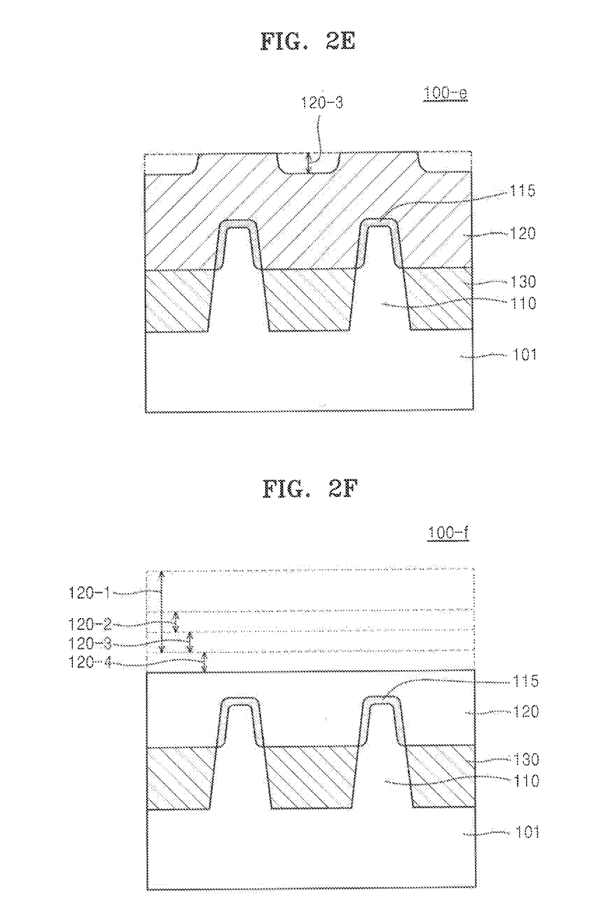

FIGS. 3A and 3B are cross-sectional views showing a method of planarizing the gate electrode material film 120 when the sacrificial material film 200 of FIG. 2B is over-etched to be lower than a stepped portion that is formed according to a height of a gate.

As described above, chemical mechanical polishing may be used to remove the sacrificial material film 200 until a top surface of the gate electrode material film 120 is exposed as shown in FIGS. 2B and 2C. When the chemical mechanical polishing is used, dishing may occur according to the chemical mechanical polishing conditions. The sacrificial material film 200 between protruding portions of the gate electrode material film 120 may be entirely removed at a position where a relatively large amount of etching is performed or may be entirely removed unless a desired end point is controlled.

Referring to FIG. 3A, when the chemical mechanical polishing is performed, an etch rate in a first region 110-a may he higher than that in a second region 110-b. The chemical mechanical polishing may be stopped as soon as the gate electrode material film 120 is detected as an end point in the first region 110-a. When the second region 110-b is etched less than the first region 110-a, a top surface of the gate electrode material film 120 need not be exposed in the second region 110-b. When the sacrificial material film 200 is over-etched, when the gate electrode material film 120 may be partially exposed and etching may be stopped, the sacrificial material film 200 might not act as an etching mask in a semiconductor device, and the series of subsequent processes of FIGS. 2D through 2F might not be performable.

FIG. 3B is a cross-sectional view showing a method of removing a stepped portion of the gate electrode material film 120 formed by the over-etching that may occur according to FIG. 3A.

Referring to FIG. 3B, the gate electrode material film 120 of the second region 110-b in which the sacrificial material film 200 is not completely removed may be planarized. For example, the sacrificial 200 of the first region 110-a of FIG. 3A may display dishing and may he planarized. When etching is stopped in a state where the gate electrode material film 120 is not exposed in the second region 110-b, the gate electrode material film 120 may be exposed by additionally performing arbitrary etching. For example, wet etching using an etchant having an etch selectivity between the sacrificial material film 200 and the gate electrode material film 120 may be used. When wet etching is used, the sacrificial material film 200 may be removed at substantially the same etching speed in the first region 110-a and the second region 110-b.

When the process of FIG. 2D is continuously performed and dishing occurs during chemical mechanical polishing, a phenomenon where the sacrificial material film 200 that is to be used as an etching mask is entirely removed may he prevented.

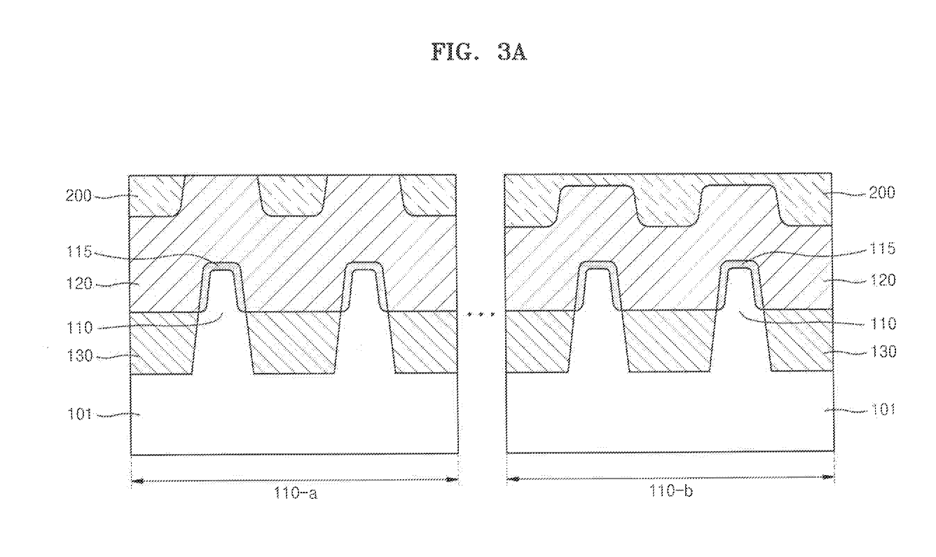

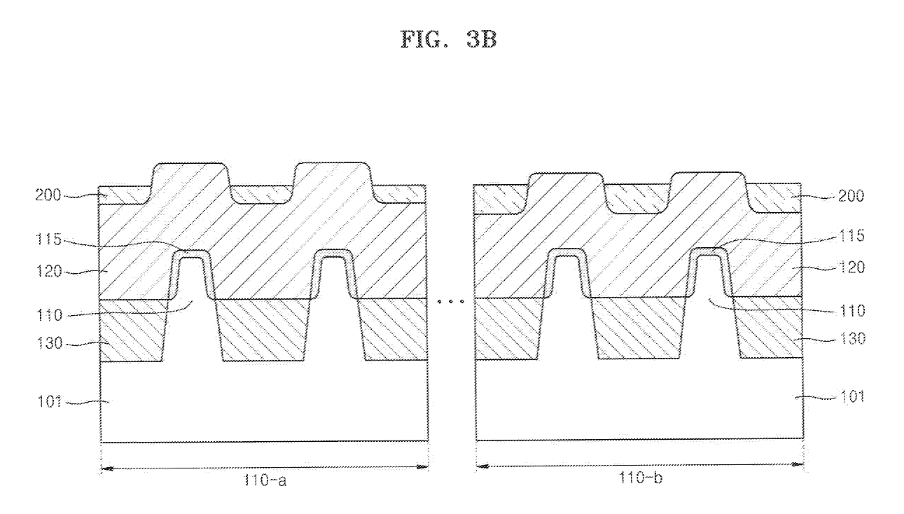

FIGS. 4A and 4B are cross-sectional views showing a process of removing the stepped portion of the gate by uniformly etching the gate electrode material film 120 and the sacrificial material film 200 of FIG. 2C according to an exemplary embodiment of the present inventive concept.

Referring to FIG. 4A, the semiconductor device may be etched by an EPD method using a selectivity difference between films as shown in FIG. 2B until the gate electrode material film 120 is exposed. The sacrificial material film 200 of FIG. 4A may include a material that has an etch selectivity different from that of the gate electrode material film 120, for example, silicon oxide, a carbon-based material, or silicon nitride. The sacrificial material film 200 may include TEOS. The process of FIG. 4A may be different from the process of FIG. 2C in that etching may be uniformly performed by a fifth stepped portion 120-5 without an etch selectivity. The process will be explained with reference to FIG. 4B.

Referring to FIG. 4B the entire sacrificial material film 200 and a part of the gate electrode material film 120 may be removed according to the fifth stepped portion 120-5 shown in FIG. 4A. The fifth stepped portion 120-5 may be removed by being substantially uniformly etched without an etch selectivity. For example, a gate poly film and an oxide film may be uniformly etched at a ratio of 1:1. The etching may include chemical mechanical polishing, dry etching, or wet etching in which etching conditions are desirably adjusted to achieve uniform etching. For example, the etching may include a gas cluster ion beam (GCIB) process.

The GCIB process may be a method of forming clusters by adiabatically expanding a high pressure gas into a vacuum state and cooling and condensing the same. The GCIB process may be used to planarize a surface of a film with the clusters that include nano-sized bits of crystalline matters. The high pressure gas may include an argon gas. A B₂H₆ gas may be used to planarize a surface of a film and a NF₃ gas may be used during etching.

When there is no etch selectivity difference between different films in the process of FIG. 4B, etching might not be needed. The gate electrode material film 120 that has a stepped portion corresponding to a height of a fin may be planarized by being etched according to the fifth stepped portion 120-5.

FIG. 4C is a cross-sectional view illustrating an oxide film that is formed during etching using a gas cluster ion beam (GCIB) process in the operation of FIG. 4A.

Referring to FIG. 4C, after a process of etching a surface of the semiconductor device by a GCIB process, a nano-sized oxide silicon layer 300 may be formed on a surface of the gate electrode material film 120. The oxide silicon layer 300 may be formed as a process result and may be removed. The oxide silicon layer 300 may be removed by chemical mechanical polishing, dry etching, or wet etching.

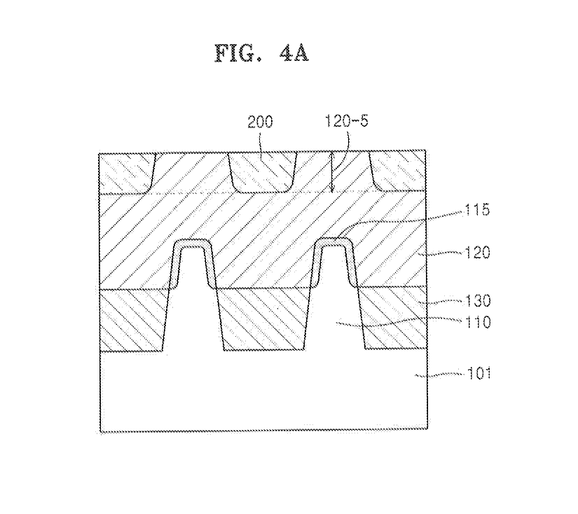

FIG. 5 is a plan view illustrating a memory module 1000 including a semiconductor device, according to an exemplary embodiment of the present inventive concept.

Referring to FIG. 5, the memory module 1000 may include a printed circuit board 1100 and a plurality of semiconductor packages 1200.

The plurality of semiconductor packages 1200 may include one or more semiconductor device(s) according to one or more exemplary embodiments of the present inventive concept. The plurality of semiconductor packages 1200 may each have a structure such as those discussed above.

The memory module 1000 may he a single in-lined memory module (SIMM) ire which the plurality of semiconductor packages 1200 is mounted on one surface of the printed circuit board 1100, or a dual in-lined memory module (DIMM) in which the plurality of semiconductor packages 1200 are mounted on both surfaces of the printed circuit board 1100. The memory module 1000 may be a full buffered DIMM (FBDIMM) including an advanced memory buffer that provides external signals to the plurality of semiconductor packages 1200.

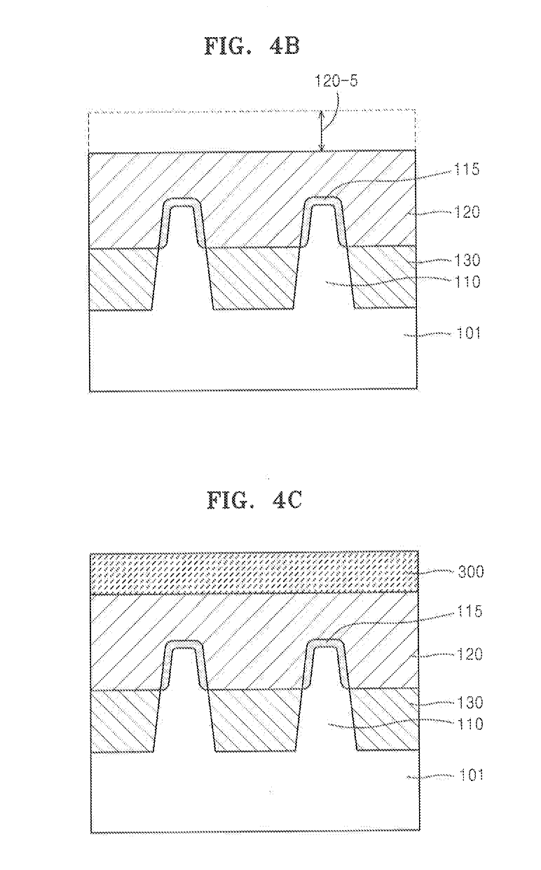

FIG. 6 is a block diagram illustrating a memory card 2000 including a semiconductor device, according to an exemplary embodiment of the present inventive concept.

Referring to FIG. 6, the memory card 2000 may be disposed such that a controller 2100 and a memory 2200 exchange an electrical signal. For example, when the controller 2100 gives a command, the memory 2200 may transmit data.

The memory 2200 may include a semiconductor device according to an exemplary embodiment of the present inventive concept. In particular, the memory 2200 may have a structure such as those discussed above.

The memory card 2000 may be any of various cards such as a memory stick card, a smart media (SM) card, a secure digital (SD) card, a mini-secure digital card, or a multimedia card (MMC).

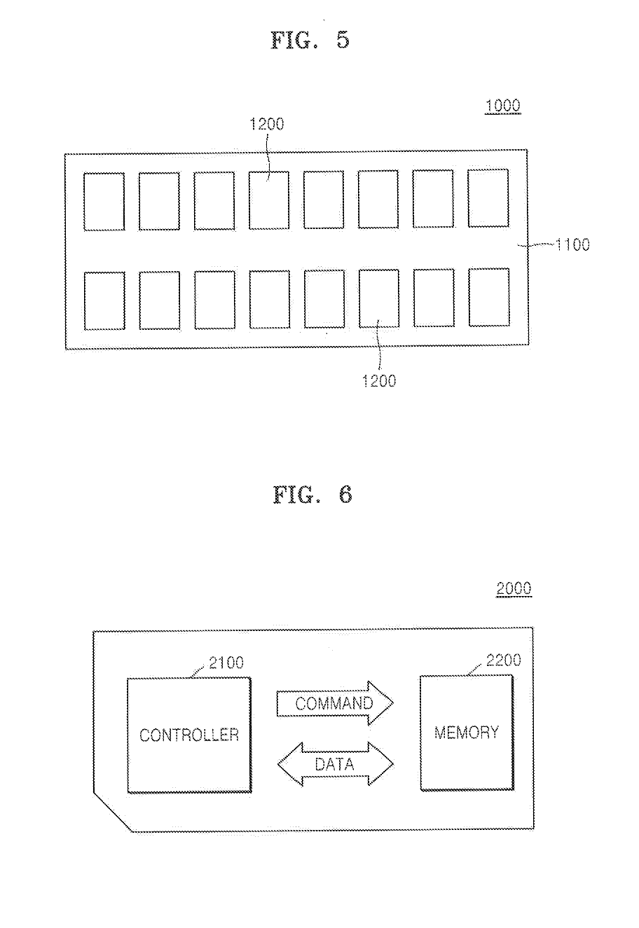

FIG. 7 is a block diagram illustrating a memory device 3200 including a semiconductor device that is formed by a method of forming an oxide layer, according to an exemplary embodiment of the present inventive concept.

Referring to FIG. 7, the memory device 3200 may include a memory module 3210. The memory module 3210 may include at least one of the semiconductor devices formed by the methods of the exemplary embodiments of the present inventive concept. The memory module 3210 may include another type of semiconductor memory device (e.g., a nonvolatile memory device and/or a static random access memory (SRAM) device). The memory device 3200 may include a memory controller 3220 that controls data exchanged between a host and the memory module 3210.

The memory controller 3220 may include a central processing unit 3222 that controls an overall operation of the memory card. The memory controller 3220 may include a SRAM 3221 that is used as an operation memory of the central processing unit 3222. The memory controller 3220 may include a host interface 3223 and a memory interface 3225. The host interface 3223 may include a data exchange protocol between the memory device 3200 and the host. The memory interface 3225 may connect the memory controller 3220 and the memory module 3210. The memory controller 3220 may include an error correction block 3224. The error correction block 3224 may detect and correct an error of data read from the memory module 3210. Although not shown, the memory device 3200 may include a ROM device that stores code data for interfacing with the host. The memory device 3200 may be a solid-state disk (SSD) that may replace a hard disk of a computer system.

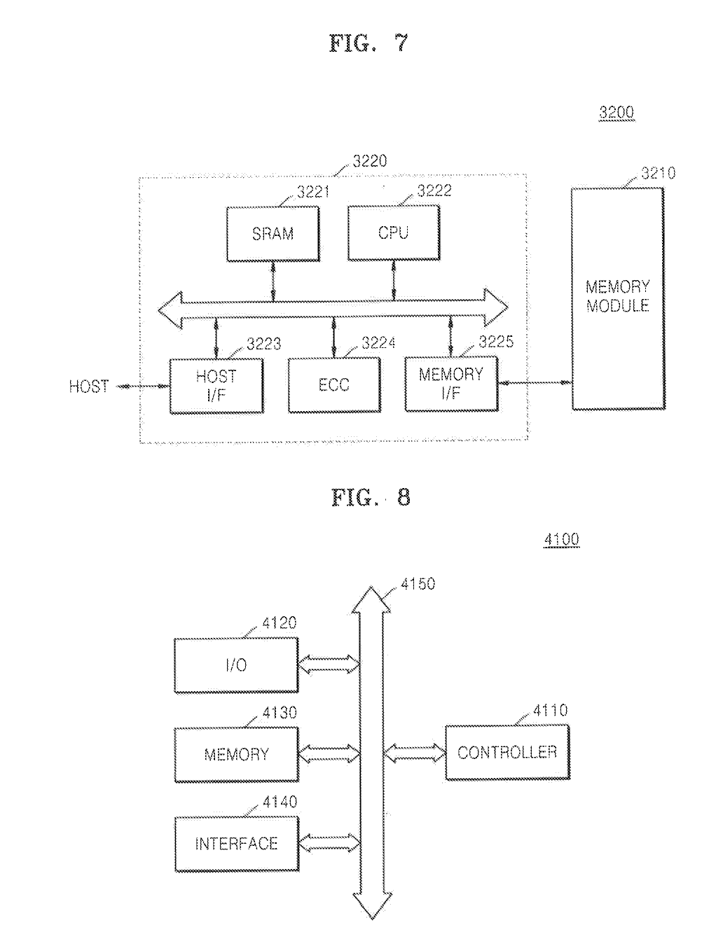

FIG. 8 is a block diagram illustrating an electronic system 4100 including a semiconductor device that is formed by a method of forming an oxide layer, according to an exemplary embodiment of the present inventive concept.

Referring to FIG. 8, the electronic system 4100 may include a controller 4110, an input/output (I/O) 4120, a memory 4130, an interface 4140, and a bus 4150. The controller 4110, the I/O 4120, the memory 4130, and/or the interface 4140 may be coupled to one another via the bus 4150. The bus 4150 may correspond to a path through which data flows,

The controller 4110 may include at least one of logic devices that may function as a microprocessor, a digital signal processor, a microcontroller, and the like. The I/O 4120 may include a keypad, a keyboard, and a display device. The memory 4130 may store data and/or a command. The memory 4130 may include at least one of the semiconductor devices of the exemplary embodiments of the present inventive concept. The memory 4130 may include another type of semiconductor device (e.g., a nonvolatile memory device and/or a SRAM device). The interface 4140 may transmit or receive data to or from a communication network. The interface 4140 may be a wired interface or a wireless interface. For example, the interface 4140 may include an antenna or a wired/wireless transceiver. Although not shown in FIG. 8, the electronic system 4100 may include a high-speed dynamic random-access memory (DRAM) device and/or a SRAM device as an operation memory device for increasing an operation of the controller 4110.

The electronic system 4100 may be applied to a personal digital assistant (PDA), a portable computer, a web tablet, a wireless phone, a mobile phone, a digital music player, a memory card, or any electronic product that wirelessly transmits and/or receives information.

While the present inventive concept has been particularly shown and described with reference to exemplary embodiments thereof, it will be understood that various changes in form and details may be made therein without departing from the spirit and scope of the present inventive concept.

What is claimed is:

1. A method of manufacturing a semiconductor device, comprising:
providing a semiconductor substrate that comprises a channel region;
forming a gate electrode material film comprising a stepped portion on the channel region;
forming a sacrificial material film on the gate electrode material film, wherein the sacrificial material film has different etch selectivity with respect to the gate electrode material film;
planarizing the sacrificial material film until a top surface of the gate electrode material film is exposed; and
reducing the stepped portion of the gate electrode material film by removing an exposed portion of the gate electrode material film.

2. The method of manufacturing a semiconductor device of claim 1, wherein the reducing of the stepped portion of the gate electrode material film comprises removing the exposed portion of the gate electrode material film by using the sacrificial material film as an etching mask.

3. The method of manufacturing a semiconductor device of claim 2, further comprising removing the sacrificial material film after using the sacrificial material film as an etching mask.

4. The method of manufacturing a semiconductor device of claim 3, further comprising removing the stepped portion by etching the gate electrode material film by chemical mechanical polishing after the removing of the sacrificial material film.

5. The method of manufacturing a semiconductor device of claim 4, wherein the removing of the stepped portion is performed for a predetermined polishing time.

6. The method of manufacturing a semiconductor device of claim 1, wherein the planarizing of the sacrificial material film comprises chemical mechanical polishing.

7. The method of manufacturing a semiconductor device of claim 1, wherein the planarizing the sacrificial material film further comprises etching the sacrificial material film by an end point detector (EPD) process using a selectivity difference between the gate electrode material film and the sacrificial material film.

8. The method of manufacturing a semiconductor device of claim 1, wherein the planarizing of the sacrificial material film further comprises over-etching the sacrificial material film so that a top surface of the sacrificial material film is lower than the top surface of the gate electrode material film.

9. The method of manufacturing a semiconductor device of claim 1, wherein the gate electrode material film is etched by dry etching.

10. The method of manufacturing a semiconductor device of claim 1, wherein the reducing of the stepped portion of the gate electrode material film comprises reducing the stepped portion by etching the gate electrode material film and the sacrificial material film,
wherein the gate electrode material film and the sacrificial material film are removed at substantially the same etch rate.

11. A method of manufacturing a semiconductor device, comprising:
providing a semiconductor substrate that comprises a channel region;
forming a gate electrode material film comprising a stepped portion on the channel region;
firming a sacrificial material film on the gate electrode material film, wherein the sacrificial material film has different etch selectivity with respect to the gate electrode material film;
etching the sacrificial material film until a top surface of the gate electrode material film is exposed; and
planarizing the stepped portion by etching the gate electrode material film and the sacrificial material film to a predetermined depth without a selectivity.

12. The method of manufacturing a semiconductor device of claim 11, wherein the etching of the sacrificial material film comprises chemical mechanical polishing.

13. The method of manufacturing a semiconductor device of claim 11, wherein the etching of the gate electrode material film and the sacrificial material film comprises etching the gate electrode material film and the sacrificial material film at substantially the same etch speed.

14. The method of manufacturing a semiconductor device of claim 11, wherein the etching of the gate electrode material film and the sacrificial material film comprises a gas cluster ion beam (GCIB) process.

15. The method of manufacturing a semiconductor device of claim 14, further comprising removing an oxide film that is formed when the GCIB process is performed.

16. A method of manufacturing a semiconductor device, comprising:
providing a bulk substrate comprising a channel region, wherein a fin is formed in the channel region;
forming a gate electrode material film comprising a stepped portion on the channel region, wherein a height of the stepped portion corresponds with a height of the fin;
forming a sacrificial material film on the gate electrode material film, wherein the sacrificial material film has different etch selectivity with respect to the gate electrode material film on the gate electrode material film;
planarizing the sacrificial material film until a top surface of the gate electrode material film is exposed; and
selectively reducing the stepped portion by etching the gate electrode material film and the sacrificial material film to a predetermined depth.

17. The method of manufacturing a semiconductor device of claim 16, wherein the reducing of the stepped portion of the gate electrode material film comprises removing the exposed portion of the gate electrode material film by using the sacrificial material film as an etching mask.

18. The method of manufacturing a semiconductor device of claim 16, wherein the planarizing of the sacrificial material film comprises chemical mechanical polishing.

19. The method of manufacturing a semiconductor device of claim 1, wherein the planarizing the sacrificial material film further comprises over-etching the sacrificial material film so that a top surface of the sacrificial material film is lower than the top surface of the gate electrode material film.

20. The method of manufacturing a semiconductor device of claim 1, wherein the gate electrode material film is etched by dry etching.
